(19) United States
(12) Patent Application Publication
(10) Pub. No.: US 2022/0415939 A1
(43) Pub. Date: Dec. 29, 2022

(54) SOLID-STATE IMAGING APPARATUS, METHOD FOR MANUFACTURING THE SAME, AND ELECTRONIC DEVICE

(71) Applicant: SUPERBVUE SOLUTIONS INC., Zhuhai (CN)

(72) Inventors: Shunsuke Tanaka, Yokohama (JP); Yuki Nobusa, Yokohama (JP)

(21) Appl. No.: 17/846,260

(22) Filed: Jun. 22, 2022

(30) Foreign Application Priority Data
Jun. 29, 2021 (JP) 2021-107389

(51) Int. Cl. H01L 27/146

(52) U.S. Cl. CPC H01L 27/14605; H01L 27/14627; H01L 27/14689

(57) ABSTRACT

Disclosed are an object of the present disclosure is to provide a solid-state imaging apparatus, a method of manufacturing a solid-state imaging apparatus, and an electronic device, which are capable of realizing superior low illuminance PDAF performance and superior light shielding performance at the same time, and which are capable of realizing higher-accuracy image quality. The pixel portion 20 is divided into a central region RCTR and a peripheral region RPRP, and in all of the pixel units PUP in the peripheral region RPRP, the number NP of same-color pixels PX which a microlens MCL is responsible for making light incident thereon is 2. The number NP is less than the number NC of same-color pixels PX in which a microlens MCL is responsible for making light incident thereon in the pixel unit PUC in the central region RCTR, which is 4. Moreover, the microlens MCL adopted in the central region RCTR and the microlens MCL adopted in the peripheral region RPRP have the same shape.

### CROSS-REFERENCE TO RELATED APPLICATIONS

The present disclosure contains subject matter related to Japanese Patent Application JP 2021-107389 filed in the Japan Patent Office on Jun. 29, 2021, the entire contents of which being incorporated herein by reference.

### BACKGROUND

### 1. Technical Field

The present disclosure relates to a solid-state imaging apparatus, a method of manufacturing the solid-state imaging apparatus, and an electronic device.

### 2. Description of Related Art

Complementary metal oxide semiconductor (CMOS) image sensors have been provided for practical use as solid-state imaging apparatus (image sensor). The solid-state imaging apparatus uses a photoelectric conversion component that detects light and generates electric charges.

A CMOS image sensor generally uses three primary color filters (red (R), green (G) and blue (B)) or 4-color complementary color filters (cyan, magenta, yellow and green) to take color images.

Generally speaking, in a CMOS image sensor, a pixel is individually equipped with a color filter. The filter includes a red (R) filter that mainly transmits red light, a green (Gr, Gb) filter that mainly transmits green light and a blue (B) filter that mainly transmits blue light. Pixel units containing each of color filters are arranged squarely to form a pixel group. Multiple pixel groups are arranged in a two-dimensional manner to form a pixel array of a pixel portion. As such color filter arrangement, Bayer pattern is widely known. In addition, for example, a microlens is formed corresponding to each pixel. Moreover, in order to achieve high sensitivity or high dynamic range, a CMOS image sensor in which a plurality of same-color pixels is arranged in a Bayer pattern in each pixel unit has also been provided (e.g., referring to Patent Documents 1 and 2).

Such CMOS image sensor has been widely used a part of an electronic device such as a digital camera, a video camera, a surveillance camera, a medical endoscope, a personal computer (PC), a mobile terminal device (e.g., a mobile phone or a mobile apparatus), etc.

Especially in recent years, the miniaturization and multi-pixelization of an image sensor mounted on a mobile terminal device (e.g., a mobile phone or a mobile apparatus) have continued to progress. The pixel size has also shrunk to a size lower than 1 μm and has gradually become the mainstream. In order to maintain the high resolution brought by the multiple pixels and suppress the reduction of the pixel pitch which leads to a decrease in sensitivity or dynamic range, generally, a plurality of same-color pixels adjacent to each other are arranged, e.g., for every 4 pixels. When resolution is required, individual pixel signals are read. When high sensitivity or dynamic range performance is required, the signals of same-color pixels are added together for reading. In such CMOS image sensor, for example, a plurality of same-color pixels adjacent to each other in the pixel unit share a microlens.

In a solid-state imaging apparatus (CMOS image sensor) that a microlens is shared among a plurality of same-color pixels, the solid-state imaging apparatus can have distance information in the pixels, and has a phase detection auto focus (PDAF) function. In such CMOS image sensor, since PDAF pixels are formed in the same color in the pixel array, the sensitivity of these PDAF pixels must be corrected in a normal shooting mode.

FIG. 1 is a diagram showing an example of a pixel group of a pixel array of a solid-state imaging apparatus (CMOS image sensor) having a PDAF function and sharing a microlens by four same-color pixels (e.g., referring to Patent Document 3).

In the pixel group 1, as shown in FIG. 1, a pixel unit PU1 with Gr pixels, a pixel unit PU2 with R pixels, a pixel unit PU3 with B pixels and a pixel unit PU4 with Gb pixels are arranged in a Bayer pattern. The pixel unit PU1 is arranged with a plurality of adjacent pixels (e.g., 2×2=4) PXGrA, PXGrB, PXGrC and PXGrD with the same color (Gr). In the pixel unit PU1, a microlens MCL1 is disposed with respect to the 4 pixels PXGrA, PXGrB, PXGrC and PXGrD. The pixel unit PU2 is arranged with a plurality of adjacent pixels (e.g., 2×2=4) PXRA, PXRB, PXRC and PXRD with the same color (R). In the pixel unit PU2, a microlens MCL2 is disposed with respect to the 4 pixels PXRA, PXRB, PXRC and PXRD. The pixel unit PU3 is arranged with a plurality of adjacent pixels (e.g., 2×2=4) PXBA, PXBB, PXBC and PXBD with the same color (B). In the pixel unit PU3, a microlens MCL3 is disposed with respect to the 4 pixels PXBA, PXBB, PXBC and PXBD. The pixel unit PU4 is arranged with a plurality of adjacent pixels (e.g., 2×2=4) PXGbA, PXGbB, PXGbC and PXGbD with the same color (Gb). In the pixel unit PU4, a microlens MCL4 is disposed with respect to the 4 pixels PXGbA, PXGbB, PXGbC and PXGbD.

In this first solid-state imaging apparatus, since two adjacent pixels simultaneously function as PDAF pixels, PDAF performance at low illuminance is improved.

FIG. 2 is a diagram showing an example of a pixel group of a pixel array of a solid-state imaging apparatus (CMOS image sensor) having a PDAF function and sharing a microlens by two same-color pixels (e.g., referring to Patent Document 4).

Same as FIG. 1, in the pixel group 1a in FIG. 2, a pixel unit PU1 with Gr pixels, a pixel unit PU2 with R pixels, a pixel unit PU3 with B pixels and a pixel unit PU4 with Gb pixels are arranged in a Bayer pattern. The pixel unit PU1 is arranged with a plurality of adjacent pixels (e.g., 2×2=4) PXGrA, PXGrB, PXGrC and PXGrD with the same color (Gr). In the pixel unit PU1, microlenses MCL01, MCL02, MCL03 and MCL04 are disposed with respect to the 4 pixels PXGrA, PXGrB, PXGrC and PXGrD, respectively. The pixel unit PU2 is arranged with a plurality of adjacent pixels (e.g., 2×2=4) PXRA, PXRB, PXRC and PXRD with the same color (R). In the pixel unit PU2, microlenses MCL11, MCL12, MCL13 and MCL14 are disposed with respect to the 4 pixels PXRA, PXRB, PXRC and PXRD, respectively.

In the pixel unit PU3, a pixel PXGB with the color G is disposed to replace the pixel PXBB with the color B among four adjacent same-color (B) pixels PXBA, PXBB, PXBC and PXRD. In the pixel unit PU3, microlenses MCL20, MCL22 and MCL23 are disposed with respect to the 3 pixels PXBA, PXBC and PXBD, respectively. The pixel unit PU4 is arranged with a plurality of adjacent pixels (e.g., 2×2=4) PXGbA, PXGbB, PXGbC and PXGbD with the same color (Gb). In the pixel unit PU4, microlenses MCL31, MCL32 and MCL33 are disposed with respect to the 3 pixels PXGbB, PXGbC and PXGbD, respectively.

In addition, in the second solid-state imaging apparatus shown in FIG. 2, a microlens MCL34 is arranged across the pixel unit with respect to the pixel PXGB of the pixel unit PU3 and the pixel PXGbA of the pixel unit PU4 so as to have the PDAF function.

In the second solid-state imaging apparatus, since only one pixel functions as a PDAF pixel, the performance of the low illuminance PDAF tends to decrease. However, since the light-shielding area of the optical center is small, the light-shielding characteristic and the sensitivity ratio characteristic of the peripheral portion are improved.

Besides, a third solid-state imaging apparatus is known to have the following configuration: in each pixel unit, microlenses are disposed with respect to each pixel, respectively; and in a specific pixel unit in the pixel array, e.g., in a pixel unit having four G pixels to replace four B pixels, a microlens is disposed with respect to 4 pixels to provide a PDAF function.

### CITATION LIST

### Patent Literature

Patent Document 1: Japanese Patent Application Publication No. H11-298800
Patent Document 2: Japanese Patent No. 5471117
Patent Document 3: U.S. Pat. No. 9,793,313 B2
Patent Document 4: U.S. Pat. No. 10,249,663 B2

### SUMMARY

### Problems to be Solved by the Present Disclosure

However, in the solid-state imaging apparatus as shown in FIG. 1, since two adjacent pixels simultaneously function as PDAF pixels, low-illuminance PDAF performance is improved, but the light-shielding area of the optical center is widened such that the light-shielding characteristic and the sensitivity ratio characteristic of the peripheral portion are degraded.

Additionally, in the solid-state imaging apparatus as shown in FIG. 2, since only one pixel functions as the PDAF pixel, the low-illuminance PDAF performance tends to decrease. However, since the light-shielding area of the optical center is small, the light-shielding characteristic and the sensitivity ratio characteristic of the peripheral portion are improved. Moreover, this structure requires two kinds of different lens shapes, such that there is a disadvantage that the variation in sensitivity will increase.

Further, in the third solid-state imaging apparatus described above, since two adjacent pixels simultaneously function as PDAF pixels, the low-illuminance PDAF performance is high, and the light-shielding area of the optical center is small, such that the light-shielding characteristic and the sensitivity ratio characteristic of the peripheral portion are high. However, there still exists the following disadvantages. That is, this configuration requires two different types of lens shapes, such that the variation in sensitivity increases. Besides, since the PDAF pixel part is replaced from blue (B) to green (G), such that color correction is required, and the resolution of blue (B) is decreased.

It is an object of the present disclosure to provide a solid-state imaging apparatus, a method of manufacturing a solid-state imaging apparatus, and an electronic device, which are capable of realizing superior low illuminance PDAF (phase detection autofocus) performance and superior light shielding performance at the same time, and which are capable of realizing higher-accuracy image quality.

### Technical Means to Solve Problems

According to a first aspect of the present disclosure, a solid-state imaging apparatus includes: a pixel portion arranged with a plurality of pixel units, each of the pixel units including a plurality of same-color pixels for performing photoelectric conversion, each of the pixel units including: a back-side separation portion for separating a plurality of adjacent pixels at least in a light incident portion of a photoelectric conversion region; and at least one microlens for making light incident on the photoelectric conversion regions of at least two of the same-color pixels, wherein the pixel portion is divided into a central region and a peripheral region, and a number of the same-color pixels which light is incident thereon by the microlens or a structure of the back-side separation portion in at least a part of the pixel units of the peripheral region, is different from a number of the same-color pixels which light is incident thereon by the microlens or a structure of the back-side separation portion in the pixel units of the central region.

According to a second aspect of the present disclosure, a method for manufacturing a solid-state imaging apparatus is provided, the solid-state imaging apparatus including: a pixel portion arranged with a plurality of pixel units, each of the pixel units including a plurality of same-color pixels for performing photoelectric conversion, each of the pixel units including: a back-side separation portion for separating a plurality of adjacent pixels at least in a light incident portion of a photoelectric conversion region; and at least one microlens for making light incident on the photoelectric conversion regions of at least two of the same-color pixels, the method for manufacturing the solid-state imaging apparatus including the steps of: dividing the pixel portion into a central region and a peripheral region; and forming at least a part of the pixel units of the peripheral region as: a number of the same-color pixels which light is incident thereon by the microlens or a structure of the back-side separation portion being different from a number of the same-color pixels which light is incident thereon by the microlens or a structure of the back-side separation portion in the pixel units in the central region.

According to a third aspect of the present disclosure, an electronic device comprises: a solid-state imaging apparatus; and an optical system, configured for imaging an object in the solid-state imaging apparatus, the solid-state imaging apparatus including: a pixel portion arranged with a plurality of pixel units, each of the pixel units including a plurality of same-color pixels for performing photoelectric conversion, and each of the pixel units including: a back-side separation portion for separating a plurality of adjacent pixels at least in a light incident portion of a photoelectric conversion region; and at least one microlens for making light incident on the photoelectric conversion regions of at least two of the same-color pixels, wherein the pixel portion is divided into a central region and a peripheral region, and a number of the same-color pixels which light is incident thereon by the microlens or a structure of the back-side separation portion in at least a part of the pixel units in the peripheral region, is different from a number of the same-color pixels which light is incident thereon by the microlens or a structure of the back-side separation portion in the pixel units in the central region.

### Effects of the Present Disclosure

According to the present disclosure, superior low illuminance phase detection auto focus (PDAF) performance and superior light shielding performance can be realized at the same time, and consequently, thereby achieving higher-precision image quality can be realized.

### BRIEF DESCRIPTION OF DRAWINGS

FIG. 1 is a diagram showing an example of a pixel group of a pixel array of a solid-state imaging apparatus (CMOS image sensor) having a PDAF function in which 4 same-color pixels share a microlens.

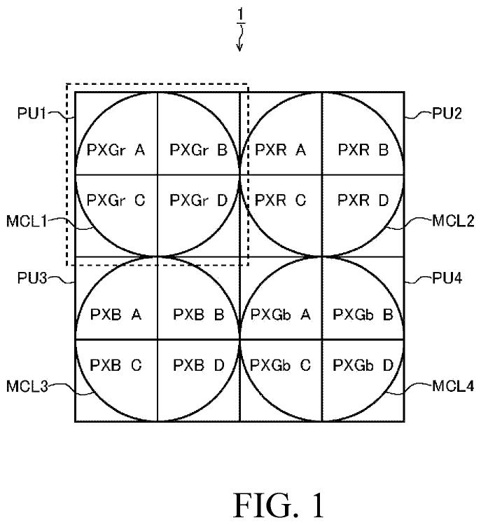

FIG. 2 is a diagram showing an example of a pixel group of a pixel array of a solid-state imaging apparatus (a CMOS image sensor) having a PDAF function in which 2 same-color pixels share a microlens.

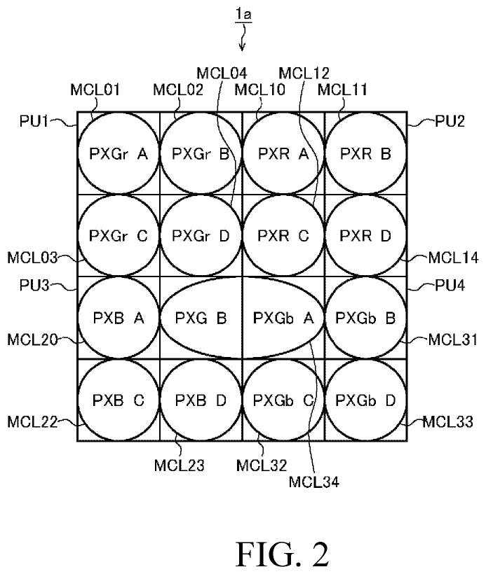

FIG. 3 is a block diagram showing a structure example of the solid-state imaging apparatus according to a first embodiment of the present disclosure.

FIG. 4 is a diagram showing a formed example of a pixel array in a pixel portion which is divided into a central region and a peripheral region according to the first embodiment of the present disclosure.

FIG. 5A and FIG. 5B are diagrams showing an example of a pixel array in a central region and a peripheral region of a pixel portion according to the first embodiment of the present disclosure.

FIG. 6 is a diagram extracting and showing an example of pixel groups forming a pixel array according to the first embodiment of the present disclosure.

FIG. 7 is a circuit diagram showing an example of a pixel unit, in which 4 pixels share a floating diffusion, of a pixel group of a solid-state imaging apparatus according to the first embodiment of the present disclosure.

FIG. 8 is a diagram showing a formed example of a pixel array in a pixel portion which is divided into a central region and a peripheral region according to a second embodiment of the present disclosure.

FIG. 9A and FIG. 9B are diagrams showing an example of a pixel array in a central region and a peripheral region of a pixel portion according to the second embodiment of the present disclosure.

FIG. 10 is a diagram showing a formed example of a pixel array in a pixel portion which is divided into a central region and a peripheral region according to a third embodiment of the present disclosure.

FIG. 11A and FIG. 11B are diagrams showing an example of a pixel array in a central region and a peripheral region of a pixel portion according to the third embodiment of the present disclosure.

FIG. 12 is a diagram showing a formed example of a pixel array in a pixel portion which is divided into a central region and a peripheral region according to a fourth embodiment of the present disclosure.

FIG. 13A and FIG. 13B are diagrams showing an example of a pixel array in a central region and a peripheral region of a pixel section according to the fourth embodiment of the present disclosure.

FIG. 14 is a diagram for explaining a formed example of the peripheral region of the pixel portion according to the arranged position of the pixel units with respect to the central region according to a fourth embodiment of the present invention.

FIG. 15 is a diagram showing a structure example of an electronic device to which the solid-state imaging apparatus is applied according to the present disclosure.

### DETAILED DESCRIPTION

The embodiments of the present disclosure are related to the drawings for description hereinafter.

### First Embodiment

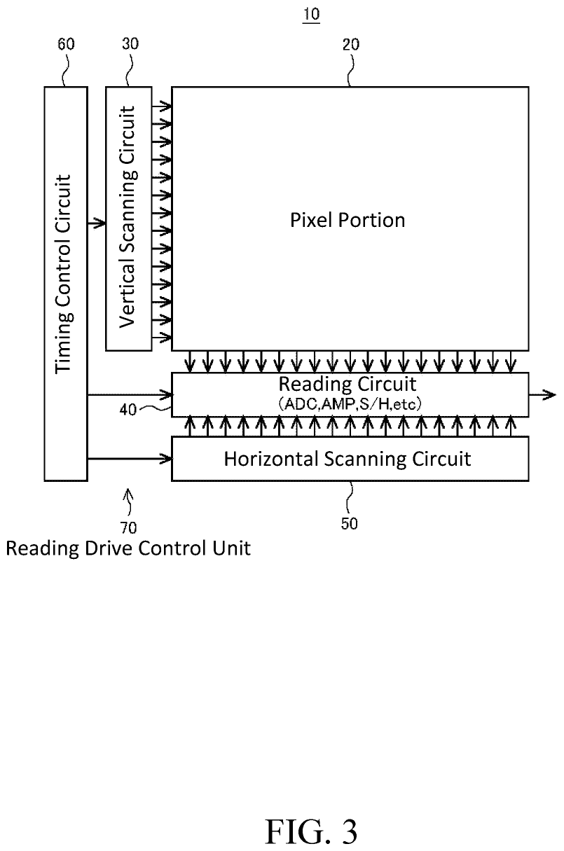

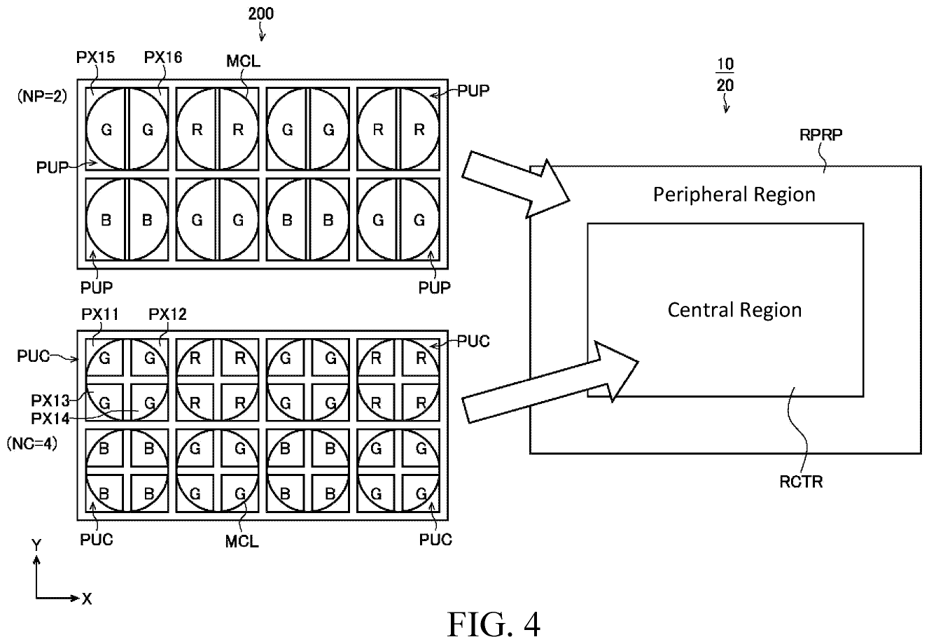

FIG. 3 is a block diagram showing a structure example of the solid-state imaging apparatus according to a first embodiment of the present disclosure. FIG. 4 is a diagram showing a formed example of a pixel array in a pixel portion which is divided into a central region and a peripheral region according to the first embodiment of the present disclosure. According to this embodiment, the solid-state imaging apparatus 10 is constituted by, for example, a CMOS image sensor.

As shown in FIG. 3, the solid-state imaging apparatus 10 mainly includes a pixel portion 20 including a pixel array, a vertical scanning circuit (a row scanning circuit) 30, a reading circuit (a column reading circuit) 40, a horizontal scanning circuit (a column scanning circuit) 50 and a timing control circuit 60. In addition, among these components, for example, the vertical scanning circuit 30, the reading circuit 40, the horizontal scanning circuit 50 and the timing control circuit 60 together constitute a reading drive control unit 70 of a pixel signal.

According to the first embodiment, in the solid-state imaging apparatus 10, as shown in FIG. 4, the pixel portion 20 is divided into a central region RCTR and a peripheral region RPRP, and a plurality of pixel units PUC, PUP which includes a plurality of same-color pixels PX for performing photoelectric conversion are arranged. In the pixel portion 20 of the first embodiment, in at least a part of the pixel units PUP of the peripheral region RPRP, the number NP of same-color pixels PX which a microlens MCL is responsible for making light incident thereon, is different from the number NC of same-color pixels PX which a microlens MCL is responsible for making light incident thereon in the pixel unit PUC of the central region RCTR.

In the first embodiment, in all the pixel units PUP of the peripheral region RPRP, the number NP of same-color pixels PX which the microlens MCL is responsible for making light incident thereon is 2. The number NP is less than the number NC of same-color pixels PX which the microlens MCL is responsible for making light incident thereon in the pixel unit PUC of the central region RCTR, which is 4.

Moreover, in the first embodiment, the microlens MCL adopted in the central region RCTR and the microlens MCL adopted in the peripheral region RPRP have the same shape.

In the pixel portion 20 of the first embodiment, in the pixel units PUC of the central region RCTR, four same-color pixels of a first same-color pixel PX11, a second same-color pixel PX12, a third same-color pixel PX13 and a fourth same-color pixel PX14 are arranged in a square such that in a first direction (e.g., an X direction), the first same-color pixel PX11 and the second same-color pixel PX12 are adjacent to each other, and the third same-color pixel PX13 and the fourth same-color pixel PX14 are adjacent to each other; and in a second direction (e.g., a Y direction) orthogonal to the first direction, the first same-color pixel PX11 and the third same-color pixel PX13 are adjacent to each other, and the second same-color pixel PX12 and the fourth same-color pixel PX14 adjacent to each other. That is, in the pixel unit PUC of the central region RCTR, four pixels of the first same-color pixel PX11, the second same-color pixel PX12, the third same-color pixel PX13 and the fourth same-color pixel PX14 are arranged in a 2×2 matrix. In addition, a microlens MCL is arranged to make light incident on the photoelectric conversion region of the first same-color pixel PX11, the photoelectric conversion region of the second same-color pixel PX12, the photoelectric conversion region of the third same-color pixel PX13 and the photoelectric conversion region of the fourth same-color pixel PX14.

In the pixel portion 20, in all of the pixel units PUP of the peripheral region RPRP, two same-color pixels of the fifth same-color pixel PX15 and the sixth same-color pixel PX16 are arranged such that the fifth same-color pixel PX15 and the sixth same-color pixel PX16 are adjacent to each other in the first direction (or alternatively, the fifth same-color pixel and the sixth same-color pixel are arranged adjacent to each other in the second direction orthogonal to the first direction). Additionally, a microlens MCL is arranged to make light incident on the photoelectric conversion region of the fifth same-color pixel PX15 and the photoelectric conversion region of the sixth same-color pixel PX16.

Hereinafter, the specific configuration, arrangement and the like of the pixel portion 20 of the solid-state imaging apparatus 10, the pixel units which include a plurality of same-color pixels (four same-color pixels in this example), and the like in the pixel portion 20, and an outline of the configuration and function of each portion are described.

(Configurations of the Pixel Array 200, the Pixel Group PXG and the Pixel Unit PU of the Pixel Portion 20)

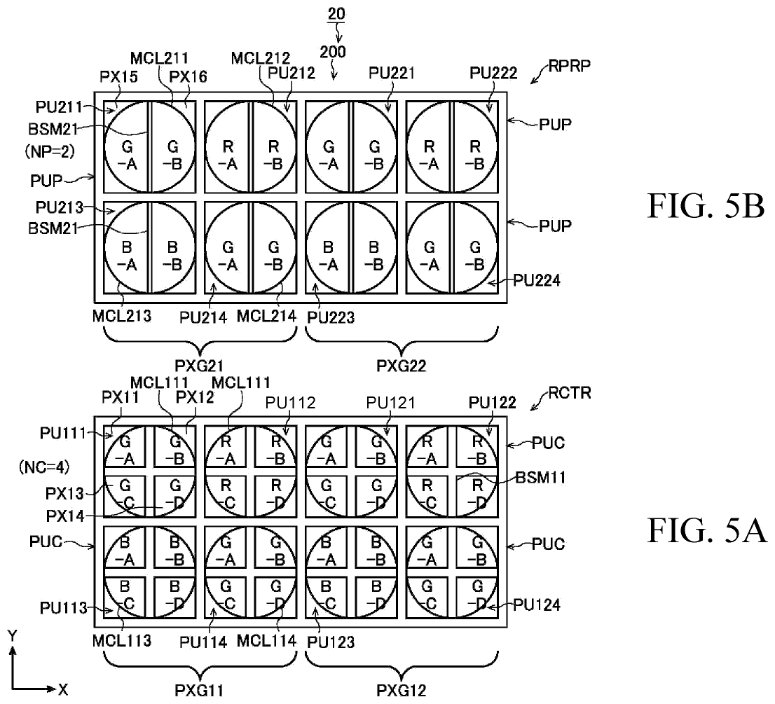

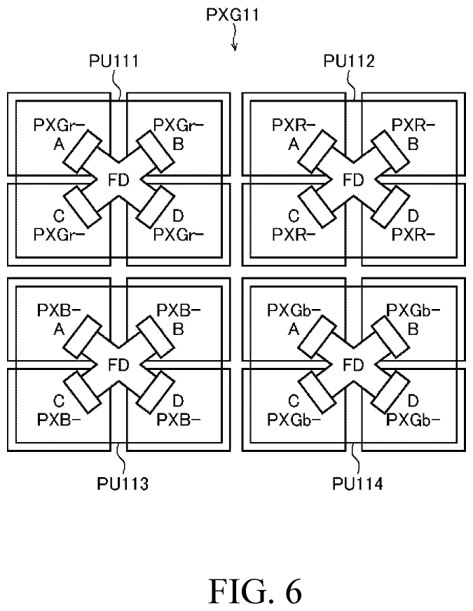

FIG. 4 is a diagram showing a formed example of a pixel array in a pixel portion which is divided into a central region and a peripheral region according to the first embodiment of the present disclosure. FIG. 5A and FIG. 5B are diagrams showing an example of a pixel array in a central region and a peripheral region of a pixel portion according to the first embodiment of the present disclosure. FIG. 5A is a diagram showing an example of a pixel array in a central region of a pixel portion according to the first embodiment of the present disclosure. FIG. 5B is a diagram showing an example of a pixel array in a peripheral region of a pixel portion according to the first embodiment of the present disclosure. FIG. 6 is a diagram extracting and showing an example of pixel groups forming a pixel array according to the first embodiment of the present disclosure.

In the present embodiment, the first direction is, for example, a row direction (a horizontal direction, an X direction), a column direction (a vertical direction, a Y direction) or an oblique direction of the pixel section 20 in which a plurality of pixels is arranged in a matrix. In the following description, as an example, the first direction is a row direction (a horizontal direction, an X direction). Accordingly, the second direction is a column direction (a vertical direction, a Y direction).

In the pixel portion 20, a pixel array 200 is formed by arranging a plurality of pixels PX which include photodiodes (photoelectric conversion units) and in-pixel amplifiers in a two-dimensional matrix.

As described above, the pixel portion 20 is divided into the central region RCTR and the peripheral region RPRP, as shown in FIGS. 4 and 5, and is arranged with a plurality of pixel units PU which include a plurality of same-color pixels PX that perform photoelectric conversion. In the pixel portion 20 of the first embodiment, in all of the pixel units PUP of the peripheral region RPRP, the number NP of same-color pixels PX which the microlens MCL is responsible for making light incident thereon is 2. The number NP is less than the number NC of same-color pixels PX which the microlens MCL is responsible for making light incident thereon in the pixel unit PUC of the central region RCTR, which is 4.

Further, in the first embodiment, the microlens MCL adopted in the central region RCTR and the microlens MCL adopted in the peripheral region RPRP have the same shape and optical characteristics. That is, the microlenses MCL adopted in the peripheral region RPRP may apply the same as those of the microlenses MCL responsible for the four same-color pixels PX of the pixel unit PUC of the central region RCTR, even if the number NP of same-color pixels is 2.

Basically, the pixel PX is composed of photodiodes and a plurality of pixel transistors. The pixel transistors include, for example, a transfer transistor, a reset transistor, a source follower transistor with an amplification function and a select transistor. However, in the first embodiment, as shown in FIG. 6, a 4-pixel sharing structure in which 4 same-color pixels in a pixel unit share a floating diffusion FD is adopted. Specifically, as described in detail later, the 4 pixels share the floating diffusion FD11, the reset transistor RST11-Tr, the source follower transistor SF11-Tr and the select transistor SEL11-Tr. Additionally, for example, when correcting the sensitivity of an arbitrary pixel, the shared floating diffusion FD is functioned as an addition portion for the pixel signals read from the plurality of pixels of the same pixel unit PU to be referred to at the time of correction.

According to the first embodiment, the pixel array 200 in the central region RCTR is configured as follows. A plurality of adjacent same-color pixels (4 pixels in the first embodiment) is arranged as a m×m (in the first embodiment is 2×2, wherein m is an integer of two or more) square to form a pixel unit PU. A pixel group PXG is formed by 4 adjacent pixel units PU, and a plurality of pixel groups PXG are arranged in a matrix. In the examples in FIGS. 4 and 5, in order to simplify the drawing, in the central region RCTR, a pixel array 200 in which 2 pixel groups PXG11 and PXG12 are arranged in a 1×2 matrix is shown.

Moreover, according to the first embodiment, the pixel array 200 in the peripheral region RPRP is configured as follows. A plurality of adjacent same-color pixels (2 pixels in the first embodiment) as are arranged a 1×1 square to form a pixel unit PUP. A pixel group PXG is formed by 4 adjacent pixel units PU, and a plurality of pixel groups PXG are arranged in a matrix. In the examples in FIGS. 4 and 5, in order to simplify the drawing, in the peripheral region RPRP, a pixel array 200 in which 2 pixel groups PXG21 and PXG22 are arranged in a 1×2 matrix is shown.

(Structure of the Pixel Group PXG and the Pixel Unit PU)

As shown in FIGS. 4 and 5, in the central region RCTR, the pixel unit PU111 of Gr pixels, the pixel unit PU112 of R pixels, the pixel unit PU113 of B pixels and the pixel unit PU114 of Gb pixels of the pixel group PXG11 are arranged in a Bayer pattern. The pixel unit PU121 of Gr pixels, the pixel unit PU122 of R pixels, the pixel unit PU123 of B pixels and the pixel unit PU124 of Gb pixels of the pixel group PXG12 are arranged in a Bayer pattern.

As shown in FIGS. 4 and 5, in the peripheral region RPRP, the pixel unit PU211 of Gr pixels, the pixel unit PU212 of R pixels, the pixel unit PU213 of B pixels and the pixel unit PU214 of Gb pixels of the pixel group PXG21 are arranged in a Bayer pattern. The pixel unit PU221 of Gr pixels, the pixel unit PU222 of R pixels, the pixel unit PU223 of B pixels and the pixel unit PU224 of Gb pixels of the pixel group PXG22 are arranged in a Bayer pattern.

In such way, the pixel groups PXG11, PXG12 and the pixel groups PXG21, PXG22 have the same structure, and are arranged in a matrix in a repetitive manner.

The pixel units constituting the pixel group of the central region RCTR also have the structure common in the pixel group. As such, the pixel units PU111, PU112, PU113 and PU114 forming the pixel group PXG11 are described here as a representative example. Similarly, the pixel units constituting the pixel group of the peripheral region RPRP also have the structure common in the pixel group. As such, the pixel units PU211, PU212, PU213 and PU214 forming the pixel group PXG21 are described here as a representative example.

In the first embodiment, the pixel unit PUC of the central region RCTR is formed with the following features.

That is, in the pixel portion 20 of the first embodiment, in the pixel units PUC of the central region RCTR, four same-color pixels of the first same-color pixel PX11, the second same-color pixel PX12, the third same-color pixel PX13, and the fourth same-color pixels PX14 are arranged in a square such that in the first direction (e.g., the X direction), the first same-color pixel PX11 and the second same-color pixel PX12 are adjacent to each other, and the third same-color pixel PX13 and the fourth same-color pixel PX14 are adjacent to each other. In addition, in the second direction (e.g., the Y direction) orthogonal to the first direction, the first same-color pixel PX11 and the third same-color pixel PX13 are adjacent to each other, and the second same-color pixel PX12 and the fourth same-color pixel PX14 are adjacent to each other. That is, in the pixel units PUC of the central region RCTR, four same-color pixels of the first same-color pixel PX11, the second same-color pixel PX12, the third same-color pixel PX13 and the fourth same-color pixel PX14 are arranged in a 2×2 matrix. Besides, a microlens MCL is arranged to make light incident on the photoelectric conversion region of the first same-color pixel PX11, the photoelectric conversion region of the second same-color pixel PX12, the photoelectric conversion region of the third same-color pixel PX13, and the photoelectric conversion region of the fourth same-color pixel PX14. Specifically, the pixel units PUC of the central region RCTR are formed as follows.

In the pixel unit PU111 of the central region RCTR, a plurality of adjacent pixels, for example, 2×2 of four pixels PXGr-A, PXGr-B, PXGr-C and PXGr-D are arranged as first to fourth same-color (Gr) pixels. In the pixel unit PU111, a microlens MCL111 is arranged for the four pixels PXGr-A, PXGr-B, PXGr-C and PXGr-D.

In the pixel unit PU112 of the central region RCTR, a plurality of adjacent pixels, for example, 2×2 of four pixels PXR-A, PXR-B, PXR-C and PXR-D are arranged as first to fourth same-color (R) pixels. In the pixel unit PU112, a microlens MCL112 is arranged for the four pixels PXR-A, PXR-B, PXR-C and PXR-D.

In the pixel unit PU113 of the central region RCTR, a plurality of adjacent pixels, for example, 2×2 of four pixels PXB-A, PXB-B, PXB-C and PXB-D are arranged as first to fourth pixels of the same-color (B) pixels. In the pixel unit PU113, a microlens MCL113 is arranged for the four pixels PXB-A, PXB-B, PXB-C and PXB-D.

In the pixel unit PU114 of the central region RCTR, a plurality of adjacent pixels, for example, 2×2 of four pixels PXGb-A, PXGb-B, PXGb-C and PXGb-D are arranged as first to fourth pixels of the same-color (Gb) pixels. In the pixel unit PU114, a microlens MCL114 is arranged for the four pixels PXGb-A, PXGb-B, PXGb-C, and PXGb-D.

The microlenses MCL111 to MCL114 have the same configuration and optical characteristics.

In each of the pixel units PU111 to PU114, the four pixels PX-A to PX-D, which are same-color pixels, are separated into four on the light incident portion of the photoelectric conversion regions PD (1 to 4) by the back-side metal BSM11 acting as a back-side separation portion. In addition, in the photoelectric conversion region PD, the back-side metal BSM11 overlaps the photoelectric conversion region PD in a depth direction to form a back-side deep trench isolation layer (BDTI) as a trench type back-side isolation layer. Accordingly, the same-color pixel PX-A includes a first photoelectric conversion region PD1, the same-color pixel PX-B includes a second photoelectric conversion region PD2, the same-color pixel PX-C includes a third photoelectric conversion region PD3, and the same-color pixel PX-D includes a fourth photoelectric conversion region PD4. Further, the pixel units having different colors are also separated by the BSM 12, or by the BSM 12 and the BDTI 12.

The other pixel groups PXG12 and the like of the central region RCTR have the same configuration as the pixel group PXG11 described above.

In the central region RCTR having such configuration, since two adjacent pixels simultaneously function as PDAF pixels, the PDAF performance at low illuminance is enhanced.

In the first embodiment, the pixel units PUP of the peripheral region RPRP are formed with the following features.

That is, in the pixel portion 20, in all of the pixel units PUP of the peripheral region RPRP, two same-color pixels of a fifth same-color pixel PX15 and a sixth same-color pixel PX16 are arranged such that the fifth same-color pixel PX15 and the sixth same-color pixel PX16 are adjacent to each other in the first direction (alternatively, the fifth same-color pixel and the sixth same-color pixel are arranged adjacent to each other in the second direction orthogonal to the first direction). In addition, a microlens MCL is arranged to make light incident on the photoelectric conversion region PD15 of the fifth same-color pixel PX15 and the photoelectric conversion region of the sixth same-color pixel PX16. Specifically, all of the pixel units PUP of the peripheral region RPRP are formed as follows.

In the pixel unit PU211 of the peripheral region RPRP, a plurality of adjacent pixels, for example, 1×1 of two pixels PXGr-A and PXGr-B are arranged as fifth and sixth same-color (Gr) pixels. In the pixel unit PU211, a microlens MCL211 is arranged for the two pixels PXGr-A and PXGr-B. The microlens MCL211 of the peripheral region RPRP has the same configuration and optical characteristics as those of the microlenses MCL111 to MCL114 applied to respective pixel units of the central region RCTR.

In the pixel unit PU212 of the peripheral region RPRP, a plurality of adjacent pixels, for example, 1×1 of two pixels PXR-A and PXR-B are arranged as fifth and sixth same-color (R) pixels. In the pixel unit PU212, a microlens MCL212 is arranged for the two pixels PXR-A and PXR-B. The microlens MCL212 of the peripheral region RPRP has the same configuration and optical characteristics as those of the microlenses MCL111 to MCL114 applied to respective pixel units of the central region RCTR.

In the pixel unit PU213 of the peripheral region RPRP, a plurality of adjacent pixels, for example, 1×1 of two pixels PXB-A and PXB-B are arranged as fifth and sixth same-color (B) pixels. In the pixel unit PU213, a microlens MCL213 is arranged for the two pixels PXB-A and PXB-B. The microlens MCL213 of the peripheral region RPRP has the same configuration and optical characteristics as those of the microlenses MCL111 to MCL114 applied to respective pixel units of the central region RCTR.

In the pixel unit PU214 of the peripheral region RPRP, a plurality of adjacent pixels, for example, 1×1 of two pixels PXGb-A and PXGb-B are arranged as fifth and sixth same-color (Gb) pixels. In the pixel unit PU214, a microlens MCL214 is arranged for the two pixels PXGb-A and PXGb-B. The microlens MCL214 of the peripheral region RPRP has the same configuration and optical characteristics as those of the microlenses MCL111 to MCL114 applied to respective pixel units of the central region RCTR.

The other pixel groups PXG22 and the like of the peripheral region RPRP have the same configuration as the pixel group PXG21 described above.

In the peripheral region RPRP having such configuration, since the light-shielding area of the optical center is small, the light-shielding characteristic and the sensitivity ratio characteristic of the peripheral portion are high. Further, since the microlenses MCL having the same shape are applied to the central region RCTR and the peripheral region RPRP, the variation in sensitivity is reduced.

In each of the pixel units PU211 to PU214, the two pixels PX-A to PX-B, which are same-color pixels, are separated into two on the light incident portion of the photoelectric conversion region PD (1 and 2) by the back-side metal BSM21 acting as the back-side separation portion. In addition, in the photoelectric conversion region PD, the back side metal BSM21 overlaps the photoelectric conversion region PD in a depth direction to form a back-side deep trench isolation layer (BDTI) as a trench type back side isolation. Thus, the same-color pixel PX-A includes a first photoelectric conversion region, and the same-color pixel PX-B includes a second photoelectric conversion region. Besides, the pixel units having different colors are also separated by the BSM 22, or by the BSM 22 and the BDTI 22.

As described above, in the first embodiment, as shown in FIG. 6, a four-pixel sharing configuration is adopted in which four same-color pixels of the pixel unit share a floating diffusion FD. Hereinafter, a structure example of four pixels sharing configuration in which four same-color pixels of the pixel unit share a floating diffusion FD is described.

(Structure Example of 4 Pixels of the Pixel Unit Sharing Configuration)

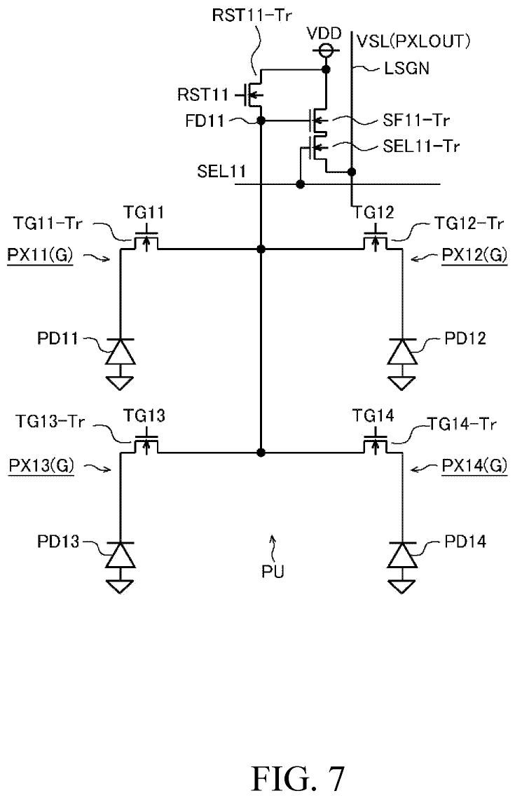

FIG. 7 is a circuit diagram showing an example of a pixel unit, in which 4 pixels share a floating diffusion, of a pixel group of a solid-state imaging apparatus according to the first embodiment of the present disclosure.

In the pixel portion 20, as shown in FIG. 7, 4 pixels (color pixels in the embodiment, G pixels herein) in the pixel unit PU of the pixel group PXG, that is, a first color pixel PX11, a second color pixel PX12, a third color pixel PX13 and a fourth color pixel PX14, are arranged in a 2×2 square.

The first color pixel PX11 is composed of a photodiode PD11 formed by a first photoelectric conversion region and a transfer transistor TG11-Tr.

The second color pixel PX12 is composed of a photodiode PD12 formed by the second photoelectric conversion region and a transfer transistor TG12-Tr.

The third color pixel PX13 is composed of a photodiode PD13 formed by the third photoelectric conversion region and a transfer transistor TG13-Tr.

The fourth color pixel PX14 is composed of a photodiode PD14 formed by the fourth photoelectric conversion region and a transfer transistor TG14-Tr.

Additionally, the pixel units PU which form the pixel group PXG share the floating diffusion FD11, a reset transistor RST11-Tr, a source follower transistor SF11-Tr and a select transistor SEL11-Tr among the 4 color pixels PX11, PX12, PX21 and PX22.

In the 4-pixel sharing structure, for example, the first color pixel PX11, the second color pixel PX12, the third color pixel PX13 and the fourth color pixel PX14 are formed in the same color, for example, as G (Gr, Gb (green)) pixels. For example, the photodiode PD11 of the first color pixel PX11 functions as a first green (G) photoelectric conversion unit. The photodiode PD12 of the second color pixel PX12 functions as a second green (G) photoelectric conversion unit. The photodiode PD13 of the third color pixel PX13 functions as a third green (G) photoelectric conversion unit. The photodiode PD14 of the fourth color pixel PX14 functions as a fourth green (G) photoelectric conversion unit.

For the photodiodes PD11, PD12, PD13 and PD14, for example, embedded photodiodes (PPD) are used. Since there are surface levels caused by defects such as dangling bonds on the surface of the substrate on which the photodiodes PD11, PD12, PD13 and PD14 are formed, a lot of charges (dark current) are generated due to thermal energy such that correct signals cannot be read. In an embedded photodiode (PPD), by embedding the charge storage part of the photodiode PD in the substrate, it is possible to reduce dark current mixing into a signal.

The photodiodes PD11, PD12, PD13 and PD14 generate and accumulate signal charges (electrons herein) corresponding to the amount of incident light. In the following, descriptions are made on the case where the signal charges are electrons and each transistor is an n-type transistor. However, the signal charges can be holes, and each transistor can be a p-type transistor.

The transfer transistor TG11-Tr is connected between the photodiode PD11 and the floating diffusion FD11, and the “on” state is controlled by the control signal TG11. Under the control of the reading control system, during the period of the control signal TG11 in the predetermined high level (H), the transfer transistor TG11-Tr is selected to be in the “on” state, and the charges (electrons) which are photoelectric converted and accumulated in photodiode PD11 are transferred to the floating diffusion FD11.

The transfer transistor TG12-Tr is connected between the photodiode PD12 and the floating diffusion FD11, and the “on” state is controlled by the control signal TG12. Under the control of the reading control system, during the period of the control signal TG12 in the predetermined high level (H), the transfer transistor TG12-Tr is selected to be in the “on” state, and the charges (electrons) which are photoelectric converted and accumulated in the photodiode PD12 are transferred to the floating diffusion FD11.

The transfer transistor TG13-Tr is connected between the photodiode PD13 and the floating diffusion FD11, and the “on” state is controlled by the control signal TG13. Under the control of the reading control system, during the period of the control signal TG13 in the predetermined high level (H), the transfer transistor TG13-Tr is selected to be in the “on” state, and the charges (electrons) which are photoelectric converted and accumulated in the photodiode PD13 are transferred to the floating diffusion FD11.

The transfer transistor TG14-Tr is connected between the photodiode PD14 and the floating diffusion FD11, and the “on” state is controlled by the control signal TG14. Under the control of the reading control system, during the period of the control signal TG14 in the predetermined high level (H), the transfer transistor TG14-Tr is selected to be in the “on” state, and the charges (electrons) which are photoelectric converted and accumulated in the photodiode PD14 are transferred to the floating diffusion FD11.

As shown in FIG. 7, the reset transistor RST11-Tr is connected between the power line VDD (or power supply potential) and the floating diffusion FD11, and the “on” state is controlled by the control signal RST11. Under the control of the reading control system, for example, when reading and scanning, during the period of the control signal RST11 in the high level H, the reset transistor RST11-Tr is selected to be in the “on” state, and resets the floating diffusion FD11 to the potential of the power line VDD (or Vrst).

The source follower transistor SF11-Tr and the select transistor SEL11-Tr are connected in series between the power line VDD and the vertical signal line LSGN. The gate of the source follower transistor SF11-Tr is connected to the floating diffusion FD11, and the “on” state of the select transistor SEL11-Tr is controlled by the control signal SEL11. During the period of the control signal SEL11 in the high level H, the select transistor SEL11-Tr is selected to be in the “on” state. Hence, the source follower transistor SF11-Tr converts the charges of the floating diffusion FD11 into a voltage signal by means of the gain of the charge amount (potential) and outputs the converted column output read voltage (signal) VSL (PXLOUT) to the vertical signal line LSGN.

In such configuration, when the transfer transistor TG11-Tr of the pixel PX11, the transfer transistor TG12-Tr of the pixel PX12, the transfer transistor TG13-Tr of the pixel PX13 and the transfer transistor TG14-Tr of the pixel PX14 are individually turned on and off, and the charges which are photoelectric converted and accumulated in the photodiodes PD11, PD12, PD13 and PD14 are sequentially transferred to the common floating diffusion FD11, the pixel signal VSL in the unit of pixel is sent to the vertical signal line LSGN and inputted to the column reading circuit 40.

On the other hand, when the transfer transistor TG11-Tr of the pixel PX11, the transfer transistor TG12-Tr of the pixel PX12, the transfer transistor TG13-Tr of the pixel PX13 and the transfer transistor TG14-Tr of the pixel PX14 are turned on and off at the same time, the transfer transistors TG12-Tr, TG13-Tr and TG14-Tr are individually turned on and off, and the charges which are photoelectric converted and accumulated in the photodiodes PD11, PD12, PD13 and PD14 are simultaneously transferred in parallel to the common floating diffusion FD11, the floating diffusion FD11 functions as an addition unit. At this time, a sum signal obtained by summing pixel signals of a plurality of pixels, i.e., 2, 3 or 4 pixels, in the pixel unit is sent to the vertical signal line LSGN, and inputted to the column reading circuit 40.

The vertical scanning circuit 30 drives the pixels in the shutter row and the reading row through row scanning control lines according to the control of the timing control circuit 60. In addition, the vertical scanning circuit 30 outputs the row select signal for the row address of the read row for reading the signal and the shutter row for resetting the charges accumulated in the photodiode PD according to the address signal.

In a normal pixel reading operating, shutter scanning is performed by driving of the vertical scanning circuit 30 of the reading control system, and then reading scanning is performed.

The reading circuit 40 may also be configured to include a plurality of column signal processing circuits (not shown) corresponding to the column outputs of the pixel portions 20, and perform column parallel processing by the plurality of column signal processing circuits.

The reading circuit 40 may include a correlated double sampling (CDS) circuit or an analog-digital converter (ADC), an amplifier (AMP) and a sample hole (S/H) circuit.

The horizontal scanning circuit 50 scans the signals processed by a plurality of column signal processing circuits such as the ADC of the reading circuit 40, transmits the signals in a horizontal direction, and outputs the signals to the reading drive control unit 70.

The timing control circuit 60 generates timing signals required for signal processing such as the pixel portion 20, the vertical scanning circuit 30, the reading circuit 40 and the horizontal scanning circuit 50.

As described above, in the first embodiment, the pixel portion 20 is divided into the central region RCTR and the peripheral region RPRP, and a plurality of pixel units PU including a plurality of same-color pixels PX that perform photoelectric conversion are arranged. In the pixel portion 20 of the first embodiment, in all of the pixel units PUP in the peripheral region RPRP, the number NP of same-color pixels PX which the microlens MCL is responsible for making light incident thereon is 2, and the number NP is less than 4 of the number NC of same-color pixels PX which the microlens MCL is responsible for making light incident thereon in the pixel unit PUC of the central region RCTR. In the first embodiment, the microlens MCL adopted in the central region RCTR and the microlens MCL adopted in the peripheral region RPRP have the same shape. That is, the microlenses MCL adopted in the peripheral region RPRP may apply the same of those have the same shape and optical characteristics as those of the microlenses MCL responsible for the four same-color pixels PX responsible for the pixel unit PUC of the central region RCTR even if the number NP of same-color pixels is 2.

As such, according to the first embodiment, since two adjacent pixels simultaneously function as PDAF pixels in the central region RCTR, the PDAF performance at low illuminance is high. Since the light-shielding area of the optical center is small in the peripheral region RPRP, the light-shielding characteristic and the sensitivity ratio characteristic of the peripheral portion are high. Moreover, the microlenses MCL having the same shape may be applied as the microlenses MCL in the central region RCTR and the peripheral region RPRP. Therefore, there are advantages in that the variation in sensitivity is small.

That is, according to the first embodiment, superior low illuminance PDAF (phase detection autofocus) performance and superior light shielding performance can be realized at the same time, and consequently, higher-accuracy image quality can be realized.

### Second Embodiment

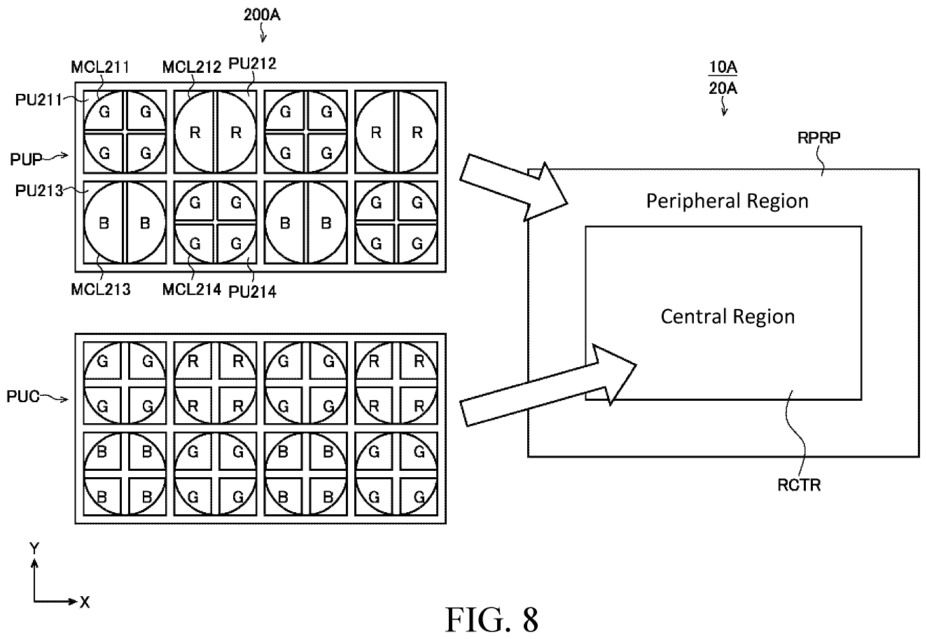

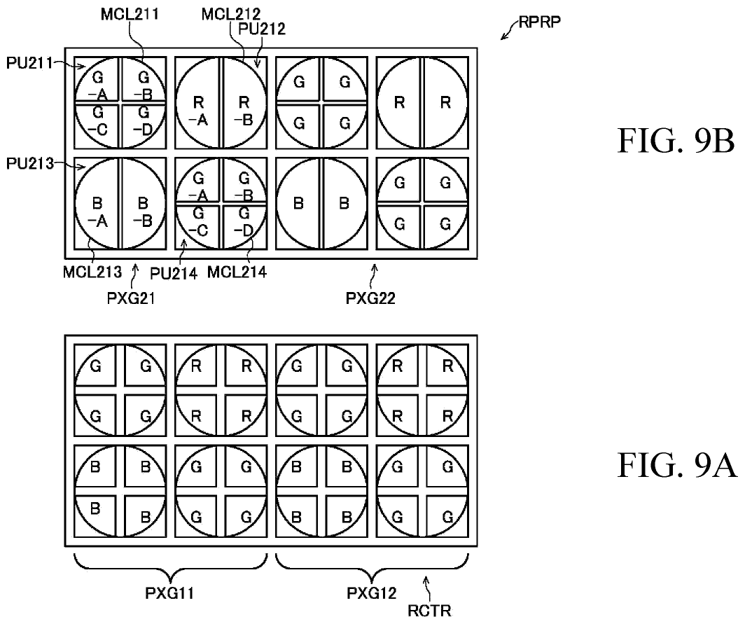

FIG. 8 is a diagram showing a formed example of a pixel array in a pixel portion which is divided into a central region and a peripheral region according to a second embodiment of the present disclosure. FIG. 9A and FIG. 9B are diagrams showing an example of a pixel array in a central region and a peripheral region of a pixel portion according to the second embodiment of the present disclosure. FIG. 9A is a diagram showing an example of a pixel array in a central region of a pixel portion according to the second embodiment of the present disclosure. FIG. 9B is a diagram showing an example of a pixel array in a peripheral region of a pixel portion according to the second embodiment of the present disclosure.

The differences between the pixel portion 20A of the second embodiment and the pixel portion 20 of the first embodiment are described as follows. In the first embodiment, in the pixel unit PUP in the peripheral region RPRP, the number NP of the same-color pixels PX which the microlens MCL is responsible for making light incident thereon is 2. The number NP is less than the number NC of same-color pixels PX which the microlens MCL is responsible for making light incident thereon in the pixel unit PUC in the central region RCTR, which is 4.

On the other hand, in the second embodiment, the number NP of same-color pixels PX which the microlens MCL is responsible for making light incident thereon in a part of the pixel units PUP in the peripheral region RPRP is 2. In this example, in the four color pixels Gr, R, B and Gb, the number NP of same-color pixels PX which the microlens MCL is responsible for making incident thereon is 2 for the R pixel and the B pixel, and the number NP of same-color pixels PX which the microlens MCL is responsible for making light incident thereon is 4 for the G (r, b) pixels.

In the example as shown in FIG. 8, in the pixel unit PU211 of the peripheral region RPRP, a plurality of adjacent pixels, for example, 2×2 of four pixels PXGr-A, PXGr-B, PXGr-C and PXGr-D are arranged as four same-color (Gr) pixels. In the pixel unit PU211, a microlens MCL211 is arranged for the four pixels PXGr-A, PXGr-B, PXGr-C and PXGr-D. The microlens MCL211 of the peripheral region RPRP has the same configuration and optical characteristics as those of the microlenses MCL111 to MCL114 applied to respective pixel units of the central region RCTR.

In the pixel unit PU212 of the peripheral region RPRP, a plurality of adjacent pixels, for example, 1×1 of two pixels PXR-A and PXR-B are arranged as fifth and sixth same-color (R) pixels. In the pixel unit PU212, a microlens MCL212 is arranged for the two pixels PXR-A and PXR-B. The microlens MCL212 of the peripheral region RPRP has the same configuration and optical characteristics as those of the microlenses MCL111 to MCL114 applied to respective pixel units of the central region RCTR.

In the pixel unit PU213 of the peripheral region RPRP, a plurality of adjacent pixels, for example, 1×1 of two pixels PXB-A and PXB-B are arranged as fifth and sixth same-color (B) pixels. In the pixel unit PU213, a microlens MCL213 is arranged for the two pixels PXB-A and PXB-B. The microlens MCL13 of the peripheral region RPRP has the same configuration and optical characteristics as those of the microlenses MCL111 to MCL114 applied to respective pixel units of the central region RCTR.

In the pixel unit PU214 of the peripheral region RPRP, a plurality of adjacent pixels, for example, 2×2 of four pixels PXGb-A, PXGb-B, PXGb-C, and PXGb-D are arranged as four same-color (Gb) pixels. In the pixel unit PU214, a microlens MCL214 is arranged for the four pixels PXb-A, PXGb-B, PXGb-C and PXGb-D. The microlens MCL214 of the peripheral region RPRP has the same configuration and optical characteristics as those of the microlenses MCL111 to MCL114 applied to respective pixel units of the central region RCTR.

The other pixel groups PXG22 and the like of the peripheral region RPRP have the same configuration as the pixel group PXG21 described above

According to the second embodiment, the same effects as those of the first embodiment described above can be obtained. That is, according to the second embodiment, the superior low illuminance PDAF (phase detection autofocus) performance and superior light shielding performance can be realized at the same time, and higher-precision image quality can be realized consequently.

### Third Embodiment

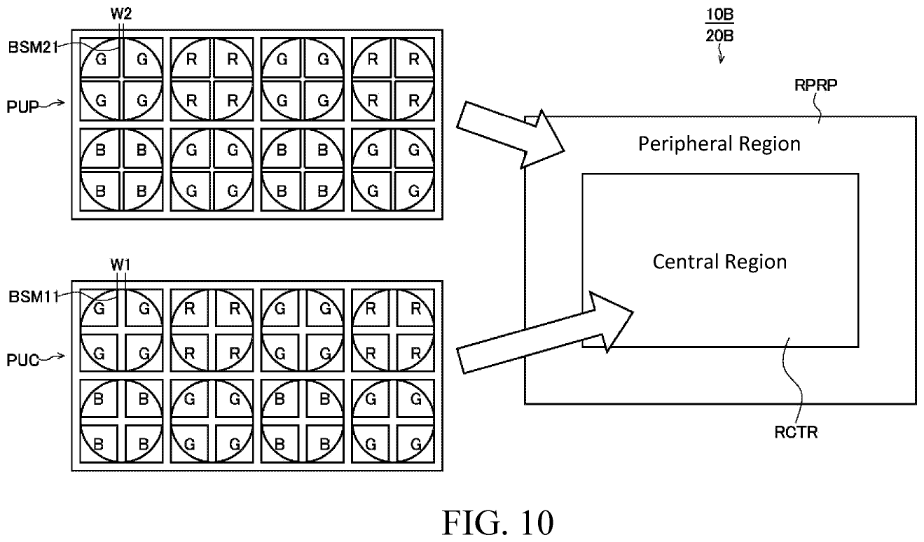

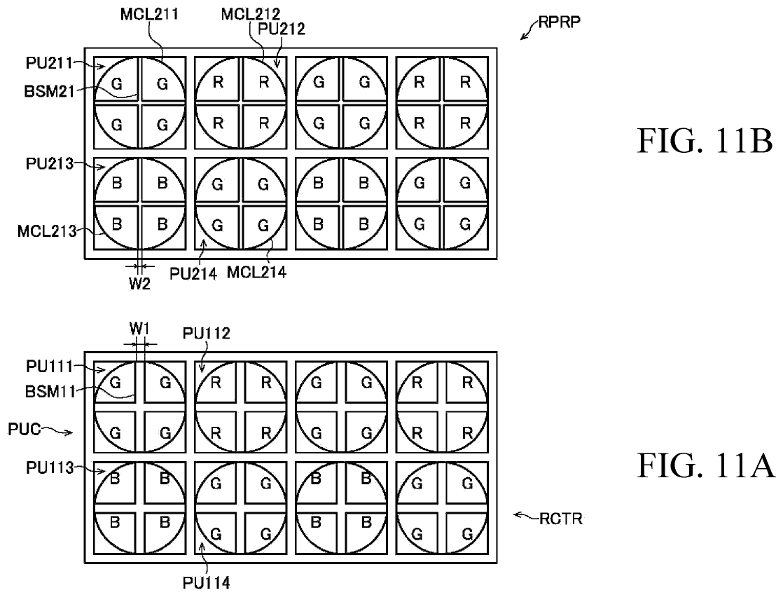

FIG. 10 is a diagram showing a formed example of a pixel array in a pixel portion which is divided into a central region and a peripheral region according to a third embodiment of the present disclosure. FIG. 11A and FIG. 11B are diagrams showing an example of a pixel array in a central region and a peripheral region of a pixel portion according to the third embodiment of the present disclosure. FIG. 11A is a diagram showing an example of a pixel array in a central region of a pixel portion according to the third embodiment of the present disclosure. FIG. 11B is a diagram showing an example of a pixel array in a peripheral region of a pixel portion according to the third embodiment of the present disclosure.

The differences between the pixel portion 20B of the third embodiment and the pixel portion 20 of the first embodiment are described as follows. In the first embodiment, in the pixel unit PUP in the peripheral region RPRP, the number NP of the same-color pixels PX which the microlens MCL is responsible for making light incident thereon is 2. The number NP is less than the number NC of same-color pixels PX which the microlens MCL is responsible for making light incident thereon in the pixel unit PUC in the central region RCTR, which is 4.

On the other hand, in the third embodiment, the number NC of same-color pixels PX which the microlenses MCL is responsible for making light incident thereon in the pixel units PUP of the peripheral region RPRP, is the same as that in the central region RCTR. Moreover, a width W2 of the back-side separation portion BSM21 between the same-color pixels in the pixel units PUP of the peripheral region RPRP, is narrower than a width W1 of the back-side separation portion BSM11 between the same-color pixels in the pixel units PUC of the central region RCTR.

According to the third embodiment, the same effects as those of the first embodiment described above can be obtained. That is, according to the third embodiment, the superior low illuminance PDAF (phase detection autofocus) performance and superior light shielding performance can be realized at the same time, and higher-precision image quality can be realized consequently.

### Fourth Embodiment

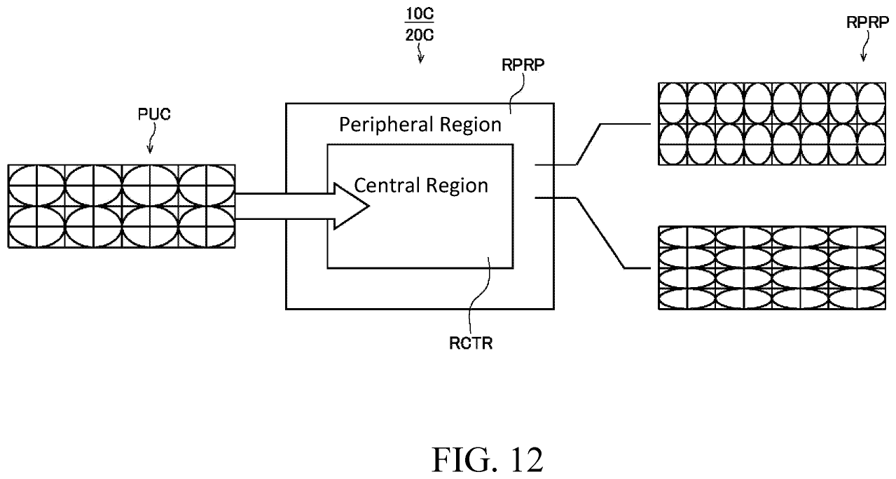

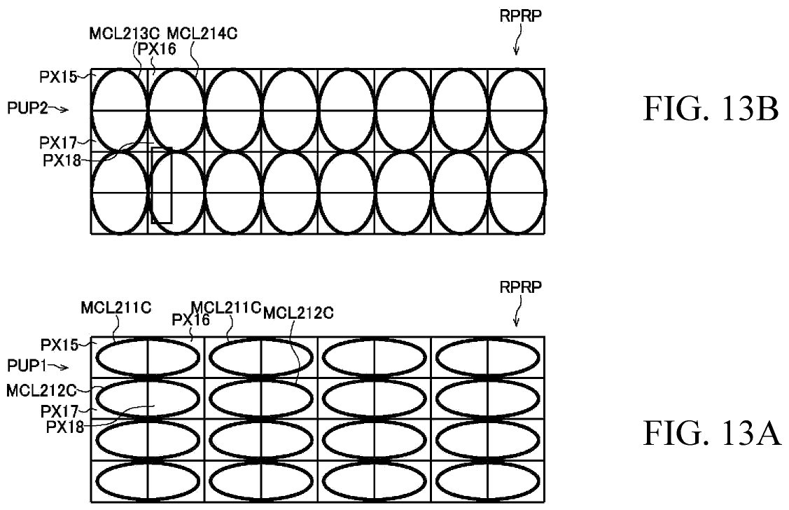

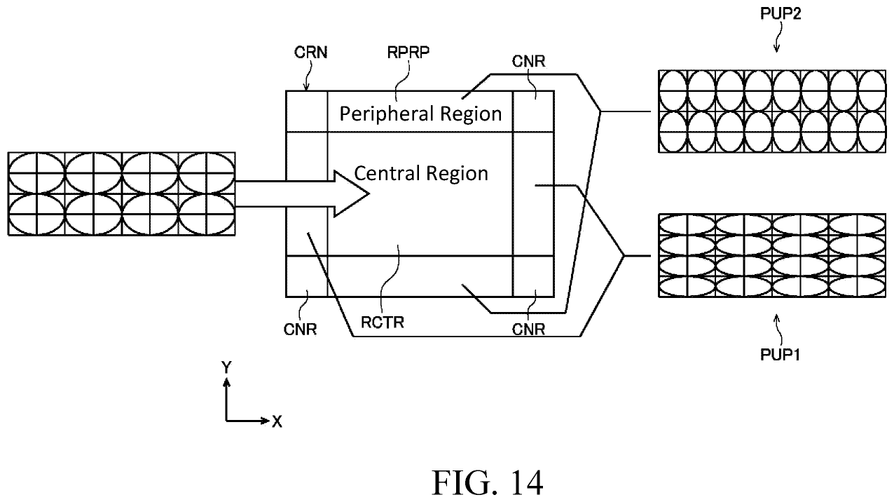

FIG. 12 is a diagram showing a formed example of a pixel array in a pixel portion which is divided into a central region and a peripheral region according to a fourth embodiment of the present disclosure. FIG. 13A and FIG. 13B are diagrams showing an example of a pixel array in a central region and a peripheral region of a pixel portion according to the fourth embodiment of the present disclosure. FIG. 13A is a diagram showing an example of a pixel array in a central region of a pixel portion according to the fourth embodiment of the present disclosure. FIG. 13B is a diagram showing an example of a pixel array in a peripheral region of a pixel portion according to the fourth embodiment of the present disclosure. FIG. 14 is a diagram for explaining a formed example of the peripheral region of the pixel portion according to the arranged position of the pixel units with respect to the central region according to a fourth embodiment of the present invention.

The differences between the pixel portion 20C of the fourth embodiment and the pixel portions 20 of the first, second and third embodiments are described as follows. In the first embodiment, the microlens MCL adopted in the central region RCTR and the microlens MCL adopted in the peripheral region RPRP have the same shape. That is, the microlenses MCL adopted in the peripheral region RPRP may apply the same as those of the microlenses MCL for the four same-color pixels PX responsible for the pixel unit PUC of the central region RCTR, even if the number NP of same-color pixels is 2.

On the other hand, in the fourth embodiment, the number of same-color pixels that the microlens MCL adopted in the peripheral region RPRP is responsible for is 2. Moreover, in the pixel unit PUP including 4 same-color pixels, first and second microlenses MCL211C and MCL212C and third and fourth microlenses MCL213C and MCL214C having shapes and optical characteristics corresponding to two pixels are adopted.

In the fourth embodiment, the pixel unit PUP of the peripheral region RPRP is formed with the following features.

That is, in the pixel portion 20C, as shown in FIGS. 12 and 13, in all or a part of the pixel units PUP of the peripheral region RPRP, four same-color pixels of the fifth same-color pixel PX15, the sixth same-color pixel PX16, the seventh same-color pixel PX17 and the eighth same-color pixel PX18 are arranged in a square such that in the first direction (e.g., the X direction), the fifth same-color pixel PX15 and the sixth same-color pixel PX16 are adjacent to each other, and the seventh same-color pixel PX17 and the eighth same-color pixel PX18 are adjacent to each other. In addition, in the second direction (e.g., the Y direction), the fifth same-color pixel PX15 and the seventh same-color pixel PX17 are adjacent to each other, and the sixth same-color pixel PX16 and the eighth same-color pixel PX18 are adjacent to each other.

As shown in FIG. 13A, a first microlens MCL211C is arranged to make light incident on the photoelectric conversion region of the fifth same-color pixel PX15 and the photoelectric conversion region of the sixth same-color pixel PX16. A second microlens MCL212C is arranged to make light incident on the photoelectric conversion region of the seventh same-color pixel PX17 and the photoelectric conversion region of the eighth same-color pixel PX 18.

Alternatively, as shown in FIG. 13B, a third microlens MCL213C is arranged to make light incident on the photoelectric conversion region of the fifth same-color pixel PX15 and the photoelectric conversion region of the seventh same-color pixel PX17. A fourth microlens MCL214C is arranged to make light incident on the photoelectric conversion region of the sixth same-color pixel PX16 and the photoelectric conversion region of the eighth same-color pixel PX 18.

Moreover, as shown in FIG. 14, the arrangement of the microlenses MCL may be selected according to the arranged position of the peripheral region RPRP with respect to the central region RCTR.

For example, in the pixel unit PUP of the peripheral region RPRP formed on a first direction side with respect to the central region RCTR, the first microlens MCL211C is arranged to make light incident on the photoelectric conversion area of the fifth same-color pixel PX15 and the photoelectric conversion area of the sixth same-color pixel PX16, and the second microlens MCL212C is arranged to make light incident on the photoelectric conversion area of the seventh same-color pixel PX17 and the photoelectric conversion area of the eighth same-color pixel PX18.

Further, in the pixel unit PUP of the peripheral region RPRP formed on a second direction side with respect to the central region RCTR, the third microlens MCL213C is arranged to make light incident on the photoelectric conversion area of the fifth same-color pixel PX15 and the photoelectric conversion area of the seventh same-color pixel PX17, and the fourth microlens MCL214C is arranged to make light incident on the photoelectric conversion area of the sixth same-color pixel PX16 and the photoelectric conversion area of the eighth same-color pixel PX18.

In the pixel unit PUP of the peripheral region RCTR formed in the corner portion CNR with respect to the central region RCTR, at least one of the following first to third arrangement methods can be applied.

In the first arrangement method, the first microlens MCL211C is arranged to make light incident on the photoelectric conversion area of the fifth same-color pixel px15 and the photoelectric conversion area of the sixth same-color pixel PX16, and the second microlens MCL212C is arranged to make light incident on the photoelectric conversion area of the seventh same-color pixel PX17 and the photoelectric conversion area of the eighth same-color pixel PX18.

In the second arrangement method, the third microlens MCL213C is arranged to make light incident on the photoelectric conversion area of the fifth same-color pixel PX15 and the photoelectric conversion area of the seventh same-color pixel PX17, and the fourth microlens MCL214C is arranged to make light is incident on the photoelectric conversion area of the sixth same-color pixel PX16 and the photoelectric conversion area of the eighth same-color pixel PX18.

In the third arrangement method, a microlens MCL211C is arranged to make light incident on the photoelectric conversion region of the fifth same-color pixel PX15, the photoelectric conversion region of the sixth same-color pixel PX16, the photoelectric conversion region of the seventh same-color pixel PX17, and the photoelectric conversion region of the eighth same-color pixel PX18.

According to the fourth embodiment, in addition to obtaining the same effects as those of the first to third embodiments, crosstalk between adjacent same-color pixels is small, and the influence of luminance shading can be further suppressed.

The solid-state imaging apparatus 10 and 10A to 10C described above can be used as a camera device to be applied to electronic devices such as digital cameras, camcorders, mobile terminal apparatus, surveillance cameras and medical endoscope cameras.

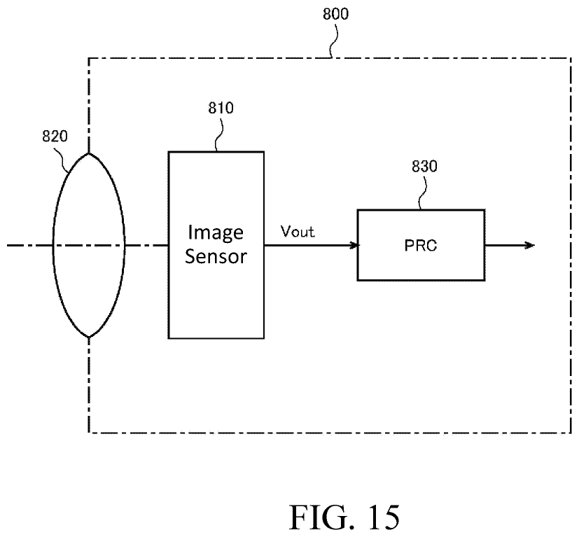

FIG. 15 is a diagram showing a structure example of an electronic device to which the solid-state imaging apparatus is applied according to the present disclosure.

As shown in FIG. 15, the electronic device 800 has a CMOS image sensor 810 to which the solid-state imaging apparatus 10 of the present disclosure can be applied. In addition, the electronic device 800 has an optical system (a lens, etc.) 820 that guides incident light to the pixel area of the CMOS image sensor 810 (imaging of an object). The electronic device 800 has a signal processing circuit (PRC) 830 for processing the output signal of the CMOS image sensor 810.

The signal processing circuit 830 performs predetermined signal processing on the output signal of the CMOS image sensor 810. The image signals processed by the signal processing circuit 830 are displayed as animations on a monitor composed of a liquid crystal display, etc., or may be outputted to a printer. Additionally, the image signals can also be directly recorded in various recording media such as a memory card.

In summary, the present disclosure can provide a high-performance, small-sized and low-cost camera system by mounting the aforementioned solid-state imaging apparatus 10 as the CMOS image sensor 810. Besides, the present disclosure can realize electronic device such as surveillance cameras, medical endoscope cameras, etc., which are used in applications where the installation requirements of the camera have restrictions on the installation size, the number of cables that can be connected, the cable length and the installation height.

What is claimed is:

1. A solid-state imaging apparatus, comprising:
a pixel portion arranged with a plurality of pixel units, each of the pixel units including a plurality of same-color pixels for performing photoelectric conversion,
each of the pixel units including:
a back-side separation portion for separating a plurality of adjacent pixels at least in a light incident portion of a photoelectric conversion region; and
at least one microlens for making light incident on the photoelectric conversion regions of at least two of the same-color pixels,
wherein the pixel portion is divided into a central region and a peripheral region, and
a number of the same-color pixels which light is incident thereon by the microlens or a structure of the back-side separation portion in at least a part of the pixel units of the peripheral region, is different from a number of the same-color pixels which light is incident thereon by the microlens or a structure of the back-side separation portion in the pixel units of the central region.

2. The solid-state imaging apparatus according to claim 1, wherein the number of the same-color pixels which light is incident thereon by the microlens in at least a part of the pixel units in the peripheral region, is less than the number of the same-color pixels which light is incident thereon by the microlens in the pixel units in the central region.

3. The solid-state imaging apparatus according to claim 1, wherein the number of the same-color pixels which light is incident thereon by the microlens in all of the pixel units in the peripheral region, is less than the number of the same-color pixels which light is incident thereon by the microlens in the pixel units in the central region.

4. The solid-state imaging apparatus according to claim 1, wherein the microlens adopted in the central region and the microlens adopted in the peripheral region have the same shape.

5. The solid-state imaging apparatus according to claim 2,
wherein in the pixel portion,
in the pixel units of the central region, four of the same-color pixels of a first same-color pixel, a second same-color pixel, a third same-color pixel and a fourth same-color pixel are arranged in a square such that in a first direction, the first same-color pixel and the second same-color pixel are adjacent to each other, and the third same-color pixel and the fourth same-color pixel are adjacent to each other; and in a second direction orthogonal to the first direction, the first same-color pixel and the third same-color pixel are adjacent to each other, and the second same-color pixel and the fourth same-color pixel are adjacent to each other; and the microlens is arranged to make light incident on a photoelectric conversion region of the first same-color pixel, a photoelectric conversion region of the second same-color pixel, a photoelectric conversion region of the third same-color pixel and a photoelectric conversion region of the fourth same-color pixel, and
in the at least a part of the pixel units of the peripheral region, two of the same-color pixels of a fifth same-color pixel and a sixth same-color pixel are arranged such that in the first direction, the fifth same-color pixel and the sixth same-color pixel are adjacent to each other, or in a second direction orthogonal to the first direction, the fifth same-color pixel and the sixth same-color pixel are adjacent to each other; and the microlens is arranged to make light incident on a photoelectric conversion region of the fifth same-color pixel and a photoelectric conversion region of the sixth same-color pixel.

6. The solid-state imaging apparatus according to claim 5, wherein
wherein in the pixel portion,
in the pixel units of the central region, four pixel units of a first pixel unit, a second pixel unit, a third pixel unit and a fourth pixel unit are arranged in a square such that in the first direction, the first pixel unit and the second pixel unit are adjacent to each other, and the third pixel unit and the fourth pixel unit are adjacent to each other; and in the second direction orthogonal to the first direction, the first pixel unit and the third pixel unit are adjacent to each other, and the second pixel unit and the fourth pixel unit are adjacent to each other; and the microlens of each of the pixel units is arranged to respectively make light incident on photoelectric conversion regions of four of the same-color pixels of the first pixel unit, photoelectric conversion regions of four of the same-color pixels of the second pixel unit, photoelectric conversion regions of four of the same-color pixels of the third pixel unit, photoelectric conversion regions of four of the same-color pixels of the fourth pixel unit, and
wherein in the pixel units of the peripheral region, four pixel units of a fifth pixel unit, a sixth pixel unit, a seventh pixel unit and an eighth pixel unit are arranged in a square such that in the first direction, the fifth pixel unit and the sixth pixel unit are adjacent to each other, and the seventh pixel unit and the eighth pixel unit are adjacent to each other; and in the second direction orthogonal to the first direction, the fifth pixel unit and the seventh pixel unit are adjacent to each other, and the sixth pixel unit and the eighth pixel unit are adjacent to each other; and the microlens of at least each of the sixth pixel unit and the seventh pixel unit is arranged to respectively make light incident on photoelectric conversion regions of two of the same-color pixels of the sixth pixel unit and photoelectric conversion regions of two of the same-color pixels of the seventh pixel unit.

7. The solid-state imaging apparatus according to claim 6, wherein the microlenses of the sixth pixel unit and the seventh pixel unit are arranged to respectively make light incident on the photoelectric conversion regions of two of the same-color pixels of the sixth pixel unit and the photoelectric conversion regions of two of the same-color pixels of the seventh pixel unit.

8. The solid-state imaging apparatus according to claim 6, wherein microlenses of the fifth pixel unit and the eighth pixel unit are arranged to respectively make light incident on the photoelectric conversion regions of four of the same-color pixels of the fifth pixel unit and photoelectric conversion regions of four of the same-color pixels of the eighth pixel unit.

9. The solid-state imaging apparatus according to claim 2,
wherein in the pixel portion,
in the pixel units of the central region, four of the same-color pixels of a first same-color pixel, a second same-color pixel, a third same-color pixel and a fourth same-color pixel are arranged in a square such that in a first direction, the first same-color pixel and the second same-color pixel are adjacent to each other, and the third same-color pixel and the fourth same-color pixel are adjacent to each other; and in a second direction orthogonal to the first direction, the first same-color pixel and the third same-color pixel are adjacent to each other, and the second same-color pixel and the fourth same-color pixel are adjacent to each other; and the microlens is arranged to make light incident on a photoelectric conversion region of the first same-color pixel, a photoelectric conversion region of the second same-color pixel, a photoelectric conversion region of the third same-color pixel and a photoelectric conversion region of the fourth same-color pixel, and
in the at least a part of the pixel units of the peripheral region, four of the same-color pixels of a fifth same-color pixel, a sixth same-color pixel, a seventh same-color pixel and an eighth same-color pixel such that in a first direction, the fifth same-color pixel and the sixth same-color pixel are adjacent to each other, and the seventh same-color pixel and the eighth same-color pixel are adjacent to each other; in a second direction orthogonal to the first direction, the fifth same-color pixel and the seventh same-color pixel are adjacent to each other, and the sixth same-color pixel and the eighth same-color pixel are adjacent to each other;
a first microlens is arranged to make light incident on a photoelectric conversion region of the fifth same-color pixel and a photoelectric conversion region of the sixth same-color pixel, and a second microlens is arranged to make light incident on a photoelectric conversion region of the seventh same-color pixel and a photoelectric conversion region of the eighth same-color pixel, or
a third microlens is arranged to make light incident on the photoelectric conversion region of the fifth same-color pixel and the photoelectric conversion region of the seventh same-color pixel, and a fourth microlens is arranged to make light incident on the photoelectric conversion region of the sixth same-color pixel and the photoelectric conversion region of the eighth same-color pixel.

10. The solid-state imaging apparatus according to claim 9, wherein in the pixel units of the peripheral region formed on the first direction side with respective to the central region, the first microlens is arranged to make light incident on the photoelectric conversion region of the fifth same-color pixel and the photoelectric conversion region of the sixth same-color pixel, and the second microlens is arranged to make light incident on the photoelectric conversion region of the seventh same-color pixel and the photoelectric conversion region of the eighth same-color pixel.

11. The solid-state imaging apparatus according to claim 9, wherein in the pixel units of the peripheral region formed on the second direction side with respective to the central region, the third microlens is arranged to make light incident on the photoelectric conversion region of the fifth same-color pixel and the photoelectric conversion region of the seventh same-color pixel, and the fourth microlens is arranged to make light incident on the photoelectric conversion region of the sixth same-color pixel and the photoelectric conversion region of the eight same-color pixel.

12. The solid-state imaging apparatus according to claim 9, wherein in the pixel units of the peripheral region formed in a corner portion with respect to the central region, at least one of the following arrangements (a) to (c) is made:
(a) the first microlens is arranged to make light incident on the photoelectric conversion region of the fifth same-color pixel and the photoelectric conversion region of the sixth same-color pixel, and the second microlens is arranged to make light incident on the photoelectric conversion region of the seventh same-color pixel and the photoelectric conversion region of the eighth same-color pixel;
(b) the third microlens is arranged to make light incident on the photoelectric conversion region of the fifth same-color pixel and the photoelectric conversion region of the seventh same-color pixel, and the fourth microlens is arranged to make light incident on the photoelectric conversion region of the sixth same-color pixel and the photoelectric conversion region of the eighth same-color pixel; and
(c) the microlens is arranged to make light incident on the photoelectric conversion region of the fifth same-color pixel, the photoelectric conversion region of the sixth same-color pixel, the photoelectric conversion region of the seventh same-color pixel and the photoelectric conversion region of the eighth same-color pixel.

13. The solid-state imaging apparatus according to claim 1, wherein a width of the back-side separation portion between the same-color pixels in at least one pixel unit in the peripheral region, is narrower than a width of the back-side separation portion between the same-color pixels in the pixel unit in the central region.

14. The solid-state imaging apparatus according to claim 13,
wherein in the pixel portion,
in the pixel units of the central region, four of the same-color pixels of a first same-color pixel, a second same-color pixel, a third same-color pixel and a fourth same-color pixel are arranged in a square such that in a first direction, the first same-color pixel and the second same-color pixel are adjacent to each other, and the third same-color pixel and the fourth same-color pixel are adjacent to each other; and in a second direction orthogonal to the first direction, the first same-color pixel and the third same-color pixel are adjacent to each other, and the second same-color pixel and the fourth same-color pixel are adjacent to each other; and the microlens is arranged to make light incident on a photoelectric conversion region of the first same-color pixel, a photoelectric conversion region of the second same-color pixel, a photoelectric conversion region of the third same-color pixel and a photoelectric conversion region of the fourth same-color pixel, and
in the at least a part of the pixel units of the peripheral region, four of the same-color pixels of a fifth same-color pixel, a sixth same-color pixel, a seventh same-color pixel and an eighth same-color pixel are arranged in a square such that in a first direction, the fifth same-color pixel and the sixth same-color pixel are adjacent to each other, and the seventh same-color pixel and the eighth same-color pixel are adjacent to each other; and in a second direction orthogonal to the first direction, the fifth same-color pixel and the seventh same-color pixel are adjacent to each other, and the sixth same-color pixel and the eighth same-color pixel are adjacent to each other; and the microlens is arranged to make light incident on a photoelectric conversion region of the fifth same-color pixel, a photoelectric conversion region of the sixth same-color pixel, a photoelectric conversion region of the seventh same-color pixel and a photoelectric conversion region of the eighth same-color pixel.

15. A method for manufacturing a solid-state imaging apparatus,
the solid-state imaging apparatus including:
a pixel portion arranged with a plurality of pixel units, each of the pixel units including a plurality of same-color pixels for performing photoelectric conversion,
each of the pixel units including:
a back-side separation portion for separating a plurality of adjacent pixels at least in a light incident portion of a photoelectric conversion region; and
at least one microlens for making light incident on the photoelectric conversion regions of at least two of the same-color pixels,
the method for manufacturing the solid-state imaging apparatus including the steps of:
dividing the pixel portion into a central region and a peripheral region, and
forming at least a part of the pixel units of the peripheral region as: a number of the same-color pixels which light is incident thereon by the microlens or a structure of the back-side separation portion being different from a number of the same-color pixels which light is incident thereon by the microlens or a structure of the back-side separation portion in the pixel units in the central region.

16. An electronic device, comprising:
a solid-state imaging apparatus; and
an optical system, configured for imaging an object in the solid-state imaging apparatus,
the solid-state imaging apparatus including:
a pixel portion arranged with a plurality of pixel units, each of the pixel units including a plurality of same-color pixels for performing photoelectric conversion, and
each of the pixel units including:
a back-side separation portion for separating a plurality of adjacent pixels at least in a light incident portion of a photoelectric conversion region; and
at least one microlens for making light incident on the photoelectric conversion regions of at least two of the same-color pixels,
wherein the pixel portion is divided into a central region and a peripheral region, and
a number of the same-color pixels which light is incident thereon by the microlens or a structure of the back-side separation portion in at least a part of the pixel units in the peripheral region, is different from a number of the same-color pixels which light is incident thereon by the microlens or a structure of the back-side separation portion in the pixel units in the central region.
